(19) United States
(12) Patent Application Publication
(10) Pub. No.: US 2004/0231600 A1
(43) Pub. Date: Nov. 25, 2004

(54) Wafer carrier locking device

(76) Inventor: Kyu Ok Lee, Gyeonggi-Do (KR)

Correspondence Address: MERCHANT & GOULD PC, P.O. BOX 2903, MINNEAPOLIS, MN, 55402-0903, US

(21) Appl. No.: 10/829,018

(22) Filed: Apr. 21, 2004

(30) Foreign Application Priority Data
Apr. 28, 2003 (KR) U2003-13105

(51) Int. Cl. C23C 16/00

(52) U.S. Cl. 118/729

(57) ABSTRACT

Disclosed herein is a wafer carrier locking device. The wafer carrier locking device includes a wafer carrier seated thereon a plurality of wafers. A main equipment executes a semiconductor manufacturing process, which is a wafer cleaning process, a wafer etching process, etc., when the wafers seated on the wafer carrier are fed to the main equipment by a multi-joint robot. An auxiliary equipment includes a carrier sensor to detect a seated state of the wafer carrier relative to a base member, a wafer sensor to detect a number and positions of the wafers seated on the wafer carrier, when the wafer carrier is seated on the base member, and the base member having a plate shape. In this case, a plurality of positioning blocks are provided at predetermined positions of the base member to allow the wafer carrier to be seated at a desired position on the base member. A locking unit is provided at a front portion of the base member to prevent the wafer carrier from being undesirably moved, when the wafer carrier is seated on the base member during the semiconductor manufacturing process of the main equipment. The wafer locking device of this invention prevents a wafer from being broken or damaged due to carelessness of a worker, and prevents a waste of resources due to the damaged wafer, and enhances productivity.

### BACKGROUND OF THE INVENTION

1. Field of the Invention

The present invention relates generally to wafer carrier locking devices, and more particularly, to a wafer carrier locking device, which is constructed to lock a wafer carrier using a hooker, when the wafer carrier is seated on a base member of an auxiliary equipment during a semiconductor manufacturing process of a main equipment, thus preventing the wafer carrier from being undesirably moved by a worker.

2. Description of the Related Art

As well known to those skilled in the art, a semiconductor process device includes a wafer carrier, a main equipment, and an auxiliary equipment. A plurality of wafers are seated on the wafer carrier. The main equipment executes a semiconductor manufacturing process, which is a wafer measuring process, a wafer cleaning process, a wafer etching process, etc., when the wafers seated on the wafer carrier are fed to the main equipment. The auxiliary equipment is provided with a base member having a shape of a plate. A plurality of positioning blocks are provided at predetermined positions of the base member so that the wafer carrier is seated at a desired position on the base member.

Such a semiconductor process device is operated as follows. That is, the wafer carrier on which a plurality of wafers are seated is moved by a worker or an automatic installation so that the wafer carrier is seated on the base member of the auxiliary equipment. Subsequently, the wafers seated on the wafer carrier are sequentially picked up by a multi-joint robot to be fed to the main equipment, and then go through the semiconductor manufacturing process, which is the wafer measuring process, the wafer cleaning process, the etching process, etc.

However, when the semiconductor manufacturing process, which is the wafer measuring process, the wafer cleaning process, the etching process, etc., is executed in the main equipment using the conventional semiconductor process device, the wafer carrier may be undesirably moved due to carelessness of a worker or an error of the automatic installation, because the conventional semiconductor process device is not provided with a locking unit to lock the wafer carrier seated on the base member of the auxiliary equipment. As such, when the wafer carrier is undesirably moved, a wafer seated on the wafer carrier is broken or damaged. Further, the rest of wafers become defective products due to particles of the damaged wafer, thus incurring economical loss and deteriorating productivity thereof.

In a detailed description, 25 sheets of wafers are seated on the wafer carrier. When the wafers are broken or damaged once due to the carelessness by a worker, a manufacturer suffers a monetary loss amounting to about thousands to hundred thousands USD. Further, when the wafers are broken or damaged, associated equipment must be stopped, thus reducing productivity.

### SUMMARY OF THE INVENTION

Accordingly, the present invention has been made keeping in mind the above problems occurring in the prior art, and an object of the present invention is to provide a wafer carrier locking device, which includes a locking unit at a semiconductor process device, thus preventing a wafer carrier from being undesirably moved due to carelessness of a worker or an error of an automatic installation, when the wafer carrier is seated on a base member of an auxiliary equipment during a semiconductor manufacturing process of a main equipment.

Another object of the present invention is to provide a wafer carrier locking device, which is capable of preventing a wafer seated on a wafer carrier from being broken or damaged, thus preventing economical loss and thereby enhancing productivity.

In order to accomplish the above object, the present invention provides a wafer carrier locking device, including a wafer carrier, a main equipment, an auxiliary equipment, and a locking unit. A plurality of wafers are seated on the wafer carrier. The main equipment executes a semiconductor manufacturing process, which is a wafer cleaning process, a wafer etching process, etc., when the wafers seated on the wafer carrier are fed to the main equipment by a multi-joint robot. The auxiliary equipment includes a carrier sensor which detects a seated state of the wafer carrier relative to a base member, a wafer sensor which detects a number and positions of the wafers seated on the wafer carrier, when the wafer carrier is seated on the base member, and the base member having a plate shape. Further, a plurality of positioning blocks are provided at predetermined positions of the base member to allow the wafer carrier to be seated at a desired position on the base member. The locking unit is provided at a front portion of the base member to prevent the wafer carrier from being undesirably moved, when the wafer carrier is seated on the base member during the semiconductor manufacturing process of the main equipment.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram of a wafer carrier locking device, according to the first embodiment of the present invention;

FIG. 2 is a perspective view of the wafer carrier locking device of FIG. 1;

FIG. 3 is an exploded perspective view of the wafer carrier locking device of FIG. 1;

FIG. 4 is a perspective view of the wafer carrier locking device of FIG. 1, when the wafer carrier locking device is unlocked;

FIG. 5 is a perspective view of the wafer carrier locking device of FIG. 1, when the wafer carrier locking device is locked;

FIGS. 6a and 6b are sectional views of the wafer carrier locking device of FIG. 1, in which FIG. 6a shows the unlocking state of the wafer carrier locking device, and FIG. 6b shows the locking state of the wafer carrier locking device;

FIG. 7 is a schematic view of a wafer carrier locking device having two locking units, according to a modification of the first embodiment;

FIG. 8 is a perspective view of a wafer carrier locking device, according to the second embodiment of the present invention; and

FIG. 9 is an enlarged view of a part of the wafer carrier locking device of FIG. 8.

### DESCRIPTION OF THE PREFERRED EMBODIMENTS

Hereinafter, embodiments of the present invention will be described in detail with reference to the accompanying drawings.

Reference now should be made to the drawings, in which the same reference numerals are used throughout the different drawings to designate the same or similar components.

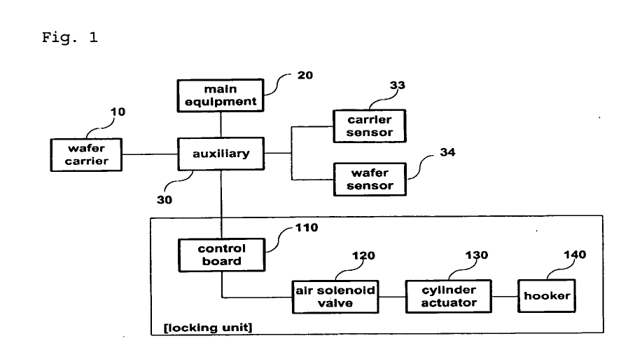

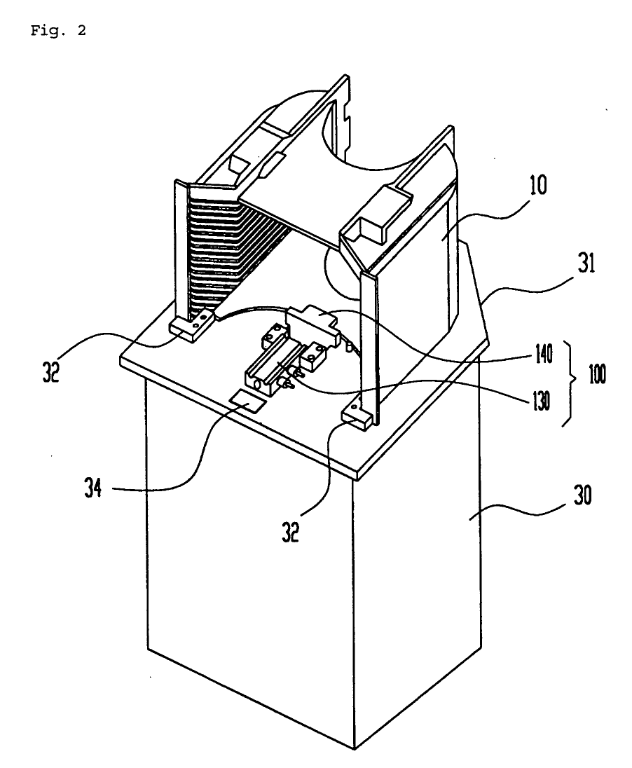

FIG. 1 is a block diagram of a wafer carrier locking device, according to the first embodiment of the present invention, and FIG. 2 is a perspective view of the wafer carrier locking device of FIG. 1. According to the first embodiment of the present invention, the wafer carrier locking device includes a wafer carrier 10, a main equipment 20, an auxiliary equipment 30, and a locking unit 100. In this case, the auxiliary equipment 30 includes a base member 31, a plurality of positioning blocks 32, a carrier sensor 33, and wafer sensors 34. The locking unit 100 is provided with a control board 110, an air solenoid valve 120, a cylinder actuator 130, and a hooker 140.

The wafer carrier 10 acts as a container which contains or carries a plurality of wafers for a semiconductor manufacturing process. The wafer carrier 10 with the wafers is manually or automatically moved by a worker or an automatic installation so that the wafer carrier 10 is seated on the base member 31 of the auxiliary equipment 30.

Further, the wafers seated on the wafer carrier 10 are fed to the main equipment 20 by a multi-joint robot (not shown). The main equipment 20 executes a semiconductor manufacturing process, which is a wafer measuring process, a wafer cleaning process, a wafer etching process, etc.

In the auxiliary equipment 30, the carrier sensor 33 detects a seated state of the wafer carrier 10 relative to the base member 31. The wafer sensors 34 detect a number and positions of the wafers seated on the wafer carrier 10 when the wafer carrier 10 is seated on the base member 31, through a scanning method. The base member 31 has a shape of a plate. The plurality of positioning blocks 32 are provided on the base member 31 to allow the wafer carrier 10 to be seated at a desired position on the base member 31.

The locking unit 100 is installed at a front portion of the base member 31 on which the wafer carrier 10 is seated. The locking unit 100 functions to lock the wafer carrier 10, thus preventing the wafer carrier 10 from being undesirably moved by a worker, when the wafer carrier 10 is seated on the base member 31 during the semiconductor manufacturing process of the main equipment 20.

The control board 110 of the locking unit 100 outputs a locking signal to the air solenoid valve 120 when a start signal of the main equipment 20 is input to the control board 110 through the auxiliary equipment 30, and outputs an unlocking signal to the air solenoid valve 120 when an end signal of the main equipment 20 is input to the control board 110 through the auxiliary equipment 30, during the semiconductor manufacturing process of the main equipment 20. In this case, the control board 110 is mounted to a lower surface of the base member 31 of the auxiliary equipment 30.

When the locking or unlocking signal is input from the control board 110 to the air solenoid valve 120, the air solenoid valve 120 of the locking unit 100 drives a pneumatic actuating unit in response to the locking or unlocking signal, thus controlling a flow of pressurized air to the cylinder actuator 130.

Further, the cylinder actuator 130 of the locking unit 100 extends or retracts according to the flow of pressurized air which is controlled by the air solenoid valve 120. As shown in FIGS. 2 through 7, the cylinder actuator 130 is installed at an upper surface of the base member 31 of the auxiliary equipment 30.

The hooker 140 of the locking unit 100 is mounted to an end of the cylinder actuator 130, and locks or unlocks the wafer carrier 10 seated on the base member 31 according to the extending or retracting motion of the cylinder actuator 130, thus preventing the wafer carrier 10 from being undesirably moved by the carelessness of the worker or the error of the automatic installation. Preferably, the hooker 140 has an L-shape. However, the hooker 140 may have various shapes, such as a U-shape.

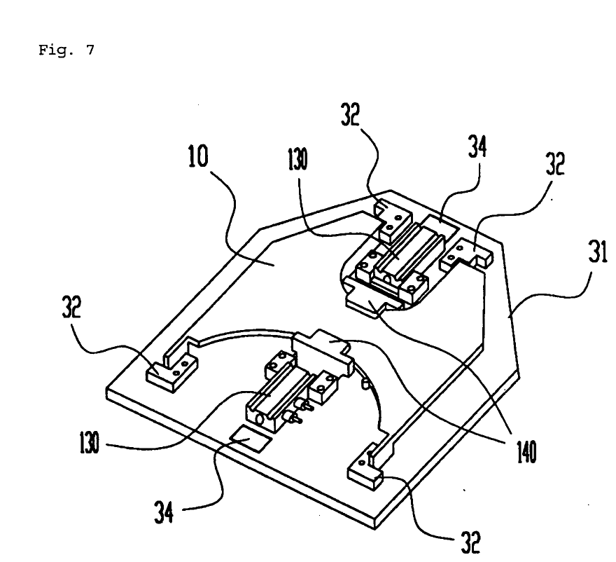

As shown in FIG. 7, the locking unit 100 may comprise a pair of locking units which are installed at positions around front and rear portions of the wafer carrier 10 seated on the base member 31.

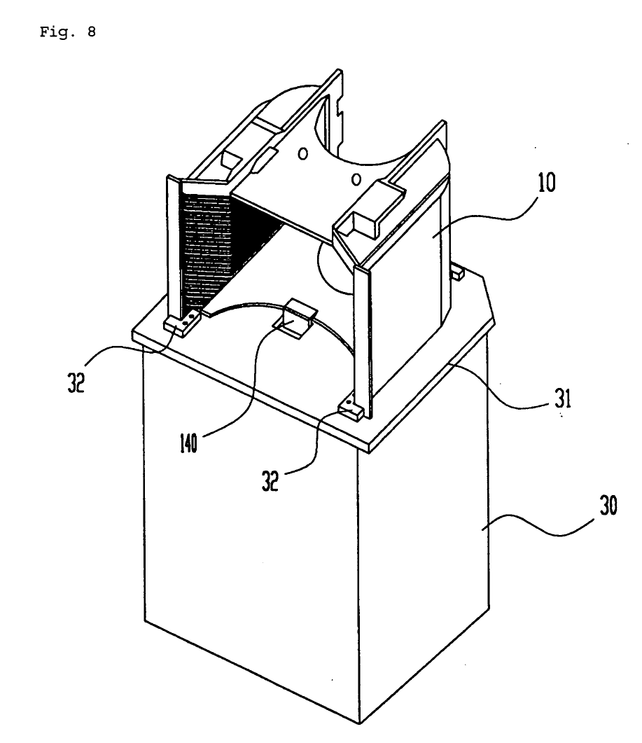

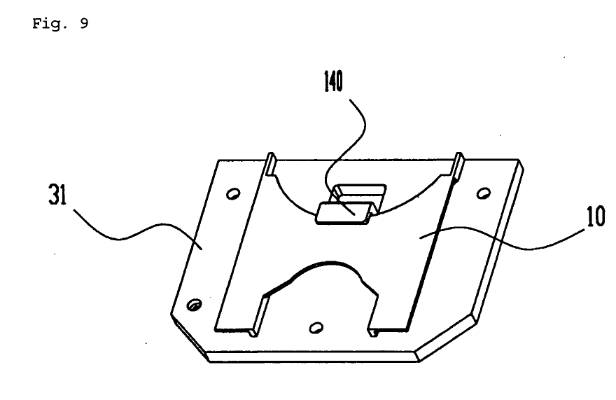

FIGS. 8 and 9 are schematic views to show a wafer carrier locking device, according to the second embodiment of the present invention. According to the second embodiment of this invention, the control board 110, the air solenoid valve 120, and the cylinder actuator 130 of the locking unit 100 are mounted to the lower surface of the base member 31 to be placed in the auxiliary equipment 30, whereas only the hooker 140 of the locking unit 100 is upwardly projected through an opening formed at a predetermined portion of the base member 31.

The operation of the wafer carrier locking device constructed as described above will be described in detail in the following with reference to the accompanying drawings.

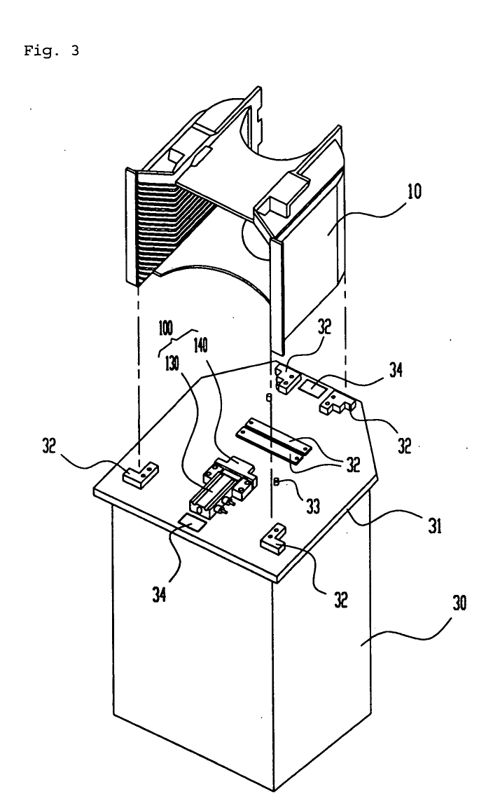

First, as shown in FIG. 3, the wafer carrier 10 seated thereon a plurality of wafers is moved by a worker or the automatic installation to be seated on the base member 31 which is provided at an upper portion of the auxiliary unit 30.

As soon as the wafer carrier 10 is seated on the base member 31, the carrier sensor 33 provided at a predetermined position of the base member 31 is pressed, thus detecting the seated state of the wafer carrier 10 relative to the base member 31. The carrier sensor 33 transmits a signal indicative of the detected information to the main equipment 20. Thereafter, the wafer sensors 34 are ejected upward to detect the positions and number of the wafers seated on the wafer carrier 10 through the scanning method.

In this case, the positions and number of the wafers seated on the wafer carrier 10 may be detected by the main equipment 20.

Next, when the main equipment 20 is ready to execute the semiconductor manufacturing process, the start signal of the main equipment 20 is input to the control board 110 of the locking unit 100 through the auxiliary equipment 30. Simultaneously, the locking signal is output to the air solenoid valve 120.

When the locking signal is input from the control board 110 to the air solenoid valve 120, the pneumatic actuating unit is driven to control a flow of pressurized air to the cylinder actuator 130.

The cylinder actuator 130 extends or retracts according to the flow of the pressurized air which is controlled by the air solenoid valve 120, so that the hooker 140 mounted at an end of the cylinder actuator 130 locks the lower surface of the wafer carrier 10 seated on the base member 31, as shown in FIGS. 2, 5, and 7.

In such a state, the semiconductor manufacturing process is executed in the main equipment 20. Thus, although the worker may make the mistake or the error of the automatic installation may occur during the semiconductor manufacturing process of the main equipment 20, the wafer carrier 10 is not moved.

After the semiconductor manufacturing process is completed, the end signal of the main equipment 20 is input through the auxiliary equipment 30 to the control board 110 of the locking unit 100. Simultaneously, the unlocking signal is output to the air solenoid valve 120. The subsequent operation will be carried out in the same order as the above-mentioned operation.

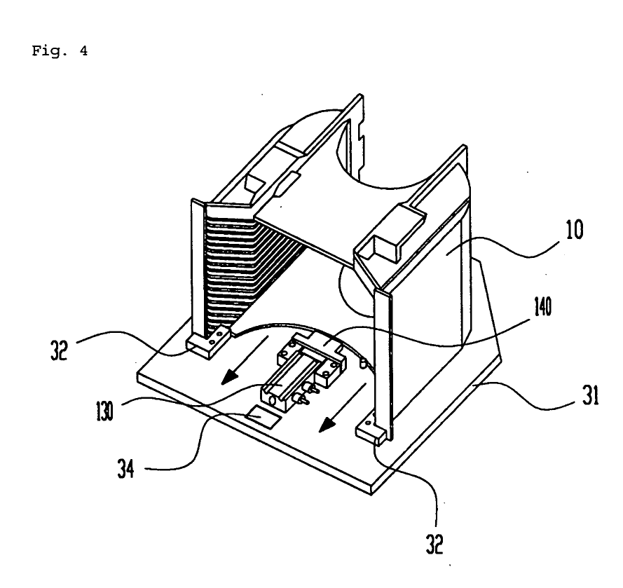

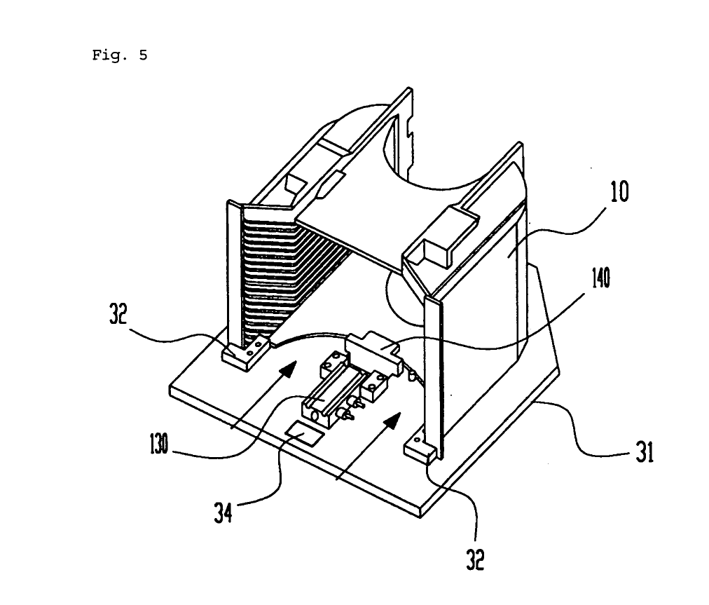

FIG. 3 is an exploded perspective view of the wafer carrier locking device of FIG. 1, and FIG. 4 shows the wafer carrier locking device of FIG. 1, when the wafer carrier locking device is unlocked, and FIG. 5 shows the wafer carrier locking device of FIG. 1, when the wafer carrier locking device is locked.

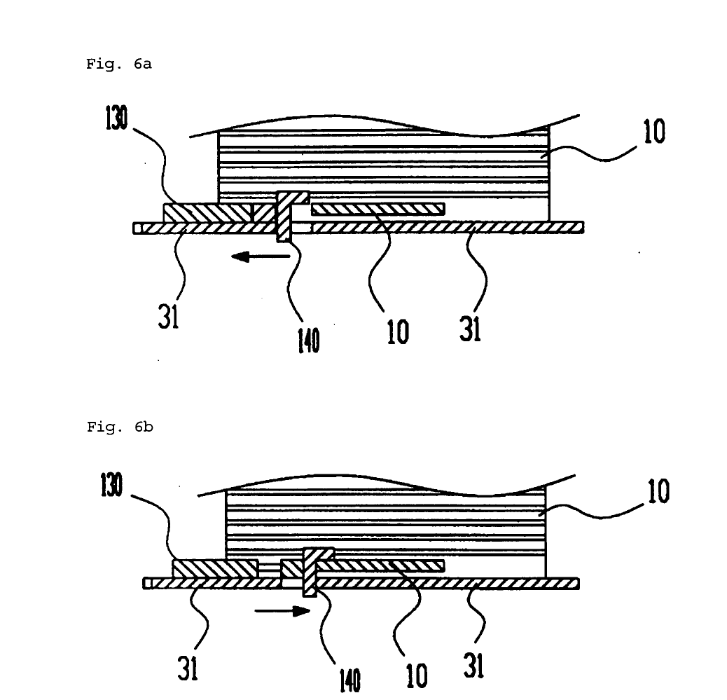

Further, FIGS. 6a and 6b are sectional views of the wafer carrier locking device of FIG. 1, in which FIG. 6a shows the unlocking state of the wafer carrier locking device, and FIG. 6b shows the locking state of the wafer carrier locking device. FIG. 7 shows a wafer carrier locking device which has two locking units at the front and rear portions of the base member 31.

Further, FIGS. 8 and 9 schematically show the wafer carrier locking device, according to the second embodiment of this invention. As shown in FIGS. 8 and 9, the control board 110, the air solenoid valve 120, and the cylinder actuator 130 of the locking unit 100 are mounted to the lower surface of the base member 31 to be placed in the auxiliary equipment 30, whereas only the hooker 140 of the locking unit 100 is upwardly projected through the opening of the base member 31.

As described above, the present invention provides a wafer carrier locking device, which is constructed to lock a wafer carrier using a hooker, when the wafer carrier is seated on a base member of an auxiliary equipment during a semiconductor manufacturing process of a main equipment, thus preventing the wafer carrier from being undesirably moved by a worker, and thereby preventing wafers from being broken or damaged due to the carelessness of the worker, therefore preventing a waste of resources due to the damaged wafers, and enhancing productivity.

Furthermore, the wafers seated on the wafer carrier are not undesirably moved by the worker without being processed, so that it is possible to prevent the worker from being confused by the mixing of the processed wafers and the unprocessed wafers.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A wafer carrier locking device, comprising:
a wafer carrier seated thereon a plurality of wafers;
a main equipment to execute a semiconductor manufacturing process, which is a wafer cleaning process, a wafer etching process, etc., when the wafers seated on the wafer carrier are fed to the main equipment by a multi-joint robot;
an auxiliary equipment, comprising:
a carrier sensor to detect a seated state of the wafer carrier relative to a base member;
a wafer sensor to detect a number and positions of the wafers seated on the wafer carrier, when the wafer carrier is seated on the base member; and
the base member having a plate shape, with a plurality of positioning blocks being provided at predetermined positions of the base member to allow the wafer carrier to be seated at a desired position on the base member; and
a locking unit provided at a front portion of the base member to prevent the wafer carrier from being undesirably moved, when the wafer carrier is seated on the base member during the semiconductor manufacturing process of the main equipment.

2. The wafer carrier locking device according to claim 1, wherein the locking unit comprises:
a control board to output a locking signal when a start signal of the main equipment is input to the control board through the auxiliary equipment, and to output an unlocking signal when an end signal of the main equipment is input to the control board through the auxiliary equipment, during the semiconductor manufacturing process of the main equipment;
an air solenoid valve to drive a pneumatic actuating unit in response to the locking signal or unlocking signal when the locking signal or unlocking signal is input from the control board to the air solenoid valve, thus controlling a flow of pressurized air;
a cylinder actuator to extend or retract according to the flow of the pressurized air controlled by the air solenoid valve; and
a hooker mounted to an end of the cylinder actuator to lock or unlock the wafer carrier seated on the base member, according to the extending or retracting motion of the cylinder actuator.

3. The wafer carrier locking device according to claim 1, wherein the locking unit comprises a pair of locking units which are installed at positions around front and rear portions of the wafer carrier seated on the base member.

4. The wafer carrier locking device according to claim 2, wherein the hooker of the locking unit has an L-shape to lock a lower surface of the wafer carrier seated on the base member.
